(19) United States
(12) Patent Application Publication
(10) Pub. No.: US 2019/0311927 A1
(43) Pub. Date: Oct. 10, 2019

(54) ALUMINUM ADHERING PROCESS AND VACUUM TRANSFER CHAMBER FOR A METAL THIN FILM PLATING MACHINE

(71) Applicants: Chen-Feng Li, Taipei City (TW); Wei-Liang Chan, Taipei City (TW); Kuo-Yang Ma, Taipei City (TW); Ching-Liang I, Taipei City (TW); Yu-Hung Huang, Taipei City (TW)

(72) Inventors: Chen-Feng Li, Taipei City (TW); Wei-Liang Chan, Taipei City (TW); Kuo-Yang Ma, Taipei City (TW); Ching-Liang I, Taipei City (TW); Yu-Hung Huang, Taipei City (TW)

(21) Appl. No.: 15/949,083

(22) Filed: Apr. 10, 2018

(51) Int. Cl. H01L 21/67

(52) U.S. Cl. CPC H01L 21/67196; H01L 21/67069; H01L 21/67167

(57) ABSTRACT

An aluminum adhering process and a vacuum transfer chamber for a metal thin film plating machine. The vacuum transfer chamber includes a vacuum transfer chamber and a pre etching reacting cavity installed in a periphery of and communicated to the vacuum transfer chamber. The pre etching reacting cavity is in a very high vacuum state. The vacuum transfer chamber is installed with a robot. The aluminum adhering process includes steps of: installing a locating frame in the vacuum transfer chamber and for storing an aluminum sheet; taking the aluminum sheet from the locating sheet then transferring the aluminum sheet to the pre etching reaction chamber; plasma bombarding the aluminum sheet in the pre etching reaction chamber; and transferring the aluminum sheet back to the locating frame after a layer of aluminum is plated on an inner wall of the pre etching reacting cavity.

### FIELD OF THE INVENTION

The present invention is related to metal thin film plating machine, and in particular to an aluminum adhering process and a vacuum transfer chamber for a metal thin film plating machine.

### BACKGROUND OF THE INVENTION

Wire bonding has become a popular technology in package of ICs. Currently, bumps are used to replace golden wires for combing chips and substrates, especially used in flip chip technology. In bumping process, a layer of UBM (which is a metal thin film layer at a bottom side of the bump) is plated on a wafer, then the processes of coating optical resistors, exposing, exposure, plating metal bumps, washing optical resistors, UBM etching, etc. are preformed.

In the following, a top cover of a vacuum transfer chamber 1 is removed, but practically, the chamber 1 is sealed at a top end by using a top cover and internal thereof is vacuumed.

Referring to FIG. 1, a schematic view about the plating of UBM layer by using a metal thin film plating layer machine is illustrated. The machine contains a vacuum transfer chamber 1, a plurality of vapor removing device 2 at a periphery of and communicated to the chamber 1, at least one pre etching reactor 3, a plurality of sputtering reactors 4, a first loading interlock vacuum chamber 5a and a second loading interlock vacuum chamber 5b. The vacuum chambers 5a and 5b are communicated to a normal pressure transfer device 6. One side of the normal pressure transfer device 6 is installed with a plurality of wafer transfer boxes 7 for locating wafers 8.

In plating UBM layer process, a robot (not shown) the normal pressure transfer device 6 will transfer the wafer 8 in the wafer transfer box 7 to the first loading interlock vacuum chamber 5a. A valve between the transfer device 6 and the first loading interlock vacuum chamber 5a is closed, and the vacuum chamber 5a is vacuumed to very high vacuum. A robot 10 in the transfer chamber 1 transfers the wafer 8 to the vapor removing device 2, the pre etching reactor 3, and the plurality of sputtering rectors 4 for removing vapor, removing oxide in an aluminum electrode and forming metal thin film layer. Then the wafer is back to the vacuum chamber 5a and the pressure within the vacuum chamber 5a is returned to atmospheric pressure. The robot in the normal pressure transfer device 6 transfers the wafer 8 to the wafer transfer box 7 so as to complete the process of plating UBM layer.

In above process, when the wafer is transferred from a manufacture plant to a packaging plant, the aluminum electrode on a surface of the wafer will be oxidized. If the oxide on the aluminum electrode is not removed, in the succeeding bumping process, the contact resistor will increase greatly so that the conduction of the wafer and the circuit board installing with the wafer is bad. As a result, the product is unused.

Therefore, before, making the bump (including plating the UBM layer), the wafer is transferred to the pre etching reactor 3 for removing the oxide on the surface of the aluminum electrode by plasma. In FIG. 1, for increasing the products, two pre etching reactors 3 are installed. However, in the plasma cleaning process, some solid sub-products such s PI, PBO, carbons, etc. will generate. These materials will adhere to an inner wall of the pre etching chambers 3. When these materials are accumulated to a volume, they will fall out and form as particles which are further formed with CO, CO2, vapors, oxygen, and other undesired gases. After the pre etching process, the solid and gas micro particles will expanse to a surface of the wafer so that the aluminum electrode on the wafer will oxidize again to increase the contact resistors.

Therefore, to resolve this problem, an aluminum sheet (which may have a size of the wafer and is formed by very pure aluminum material or plating aluminum on the wafer), then it transfers to the pre etching chamber 3 to plasma bombarding these sheet so that the aluminum on the aluminum sheet is plated to an inner wall of the pre etching chamber 3 to cover the materials formed originally on plasma bombarding. Thus, the particles and undesired gases are reduced. This is so called aluminum adhering process. Generally after a predetermined number (preferably, seven) of wafers are pre etching cleaned, one time of aluminum adhering process is preformed.

With reference to FIG. 2, the prior art aluminum adhering method in a metal thin film plating layer machined is illustrated, the aluminum sheet 9 is placed on the wafer transfer box 7 and then the robot (not shown) of the normal pressure transfer device 6 is used to transferred the aluminum sheet 7 to the first loading interlock vacuum chamber 5a. The first loading interlock vacuum chamber 5a is vacuumed to a very high degree, the robot 10 in the transfer chamber 1 is used to transfer the aluminum sheet to the inner wall of pre etching chamber 3. Then the robot 10 transfer the aluminum sheet 9 to the vacuum chamber 5a. Then the vacuum chamber 5a is returned to atmosphere pressure, the robot in the normal pressure transfer device 6 transfers the aluminum sheet 9 to the wafer transfer box 7 to complete one time of aluminum adhering process. In the prior process, the aluminum sheet 9 must be transferred from a normal pressure to a very high vacuum and then returned to normal pressure. In transferring process, mass production cannot be done and a large amount of time is necessary. As a result, efficiency is very low.

With reference to FIG. 3, another prior art aluminum adhering method in a metal thin film plating layer machined is illustrated. It is shown that storage chambers 9a for storing aluminum sheets 9 are installed in a periphery of and are communicated to the vacuum transfer chamber 1. In the aluminum adhering process, the vacuuming process is undesired, while the robot 10 in the transfer chamber 1 transfers the aluminum sheets 9 in the storage chambers 9a to the pre etching chamber 3 to plasma bombarding for proceeding aluminum adhering process. Therefore, the vacuuming process is undesired, and the defect of low working efficiency is improved, but the storage chambers 9a will occupy a position of an opening of the transfer chamber 1 so as to affect other manufacturing process. For example, it will occupy a position for vapor removing device 2 so as to affect the process of vapor removing, or occupying the position of the pre etching reactor 3 to affect the pre etching cleaning process. Furthermore installation of storage chambers 9a not only increase the cost of the whole equipments, but also the valves between the vacuum transfer chamber 1 and the storage chambers 9a causes that a high vacuum drawing system is necessary for isolating the two devices. This will further increase the cost.

### SUMMARY OF THE INVENTION

To improve above mentioned defect in the prior art, the present invention provides an aluminum adhering process and vacuum transfer chamber for a metal thin film plating machine, wherein the aluminum sheet is installed in the locating frame of the vacuum transfer chamber so that in the aluminum adhering process, the operation of vacuuming and restoring pressure do not need and efficiency is increased greatly. Furthermore, the position for storing the aluminum sheet is very near the pre etching reacting cavity , and thus in the aluminum adhering process, the distance for transfer of the aluminum sheet is reduced greatly. Especially, the structure of the locating frame is very simple, and thus the cost for making the locating frame is very low. Especially, the locating frame can be directly installed in the vacuum chamber of the metal thin film plating layer machine. No storage chamber for storing the aluminum sheet temporarily is needed. The cost is greatly reduced. Furthermore the opening for vacuum transfer chamber is saved. The system for vacuuming used for the storage chamber is unnecessary and thus the cost is further reduced.

The present invention provides an aluminum adhering process for a metal thin film plating machine which includes a vacuum transfer chamber and a pre etching reacting cavity which is installed in a periphery of the vacuum transfer chamber and is communicated to the vacuum transfer chamber; the pre etching reacting cavity and the pre etching reacting cavity being in a very high vacuum state; the vacuum transfer chamber being installed with a robot; the aluminum adhering process including the following steps: (a) installing a locating frame in the vacuum transfer chamber and a location of the locating frame not affect actions of the robot to transfer a water; the locating frame being used to storing an aluminum sheet; (b) taking the aluminum sheet from the locating sheet by using the robot and then transferring the aluminum sheet to the pre etching reaction chamber; (c) plasma bombarding the aluminum sheet in the pre etching reaction chamber so that aluminum in the aluminum sheet is plated to an inner wall of the pre etching reaction chamber; and (d) transferring the aluminum sheet back to the locating frame by using the robot after a layer of aluminum is plated on the inner wall of the pre etching reacting cavity.

Further, the present invention provide a vacuum transfer chamber for a metal thin film plating machine comprising: a chamber body having a transfer space which has a vacuum space; a periphery of the chamber being formed with a plurality of openings which are communicated to the transfer space; one of the openings being communicated with a pre etching reacting cavity which is located at an outer side; a locating frame installed in the transfer space does not affect operations of transfer of the wafer; the locating frame storing at least one aluminum sheet and one wafer; and a robot installed in the transfer space for transfer of the wafer and for taking out the aluminum sheet from the locating frame and then transferring the aluminum sheet to the pre etching reacting cavity, and could return the aluminum sheet from the pre etching reacting cavity to the locating frame.

### BRIEF DESCRIPTION OF THE DRAWINGS

FIG. 1 is a schematic view showing the operation of the prior art plating UBM process.

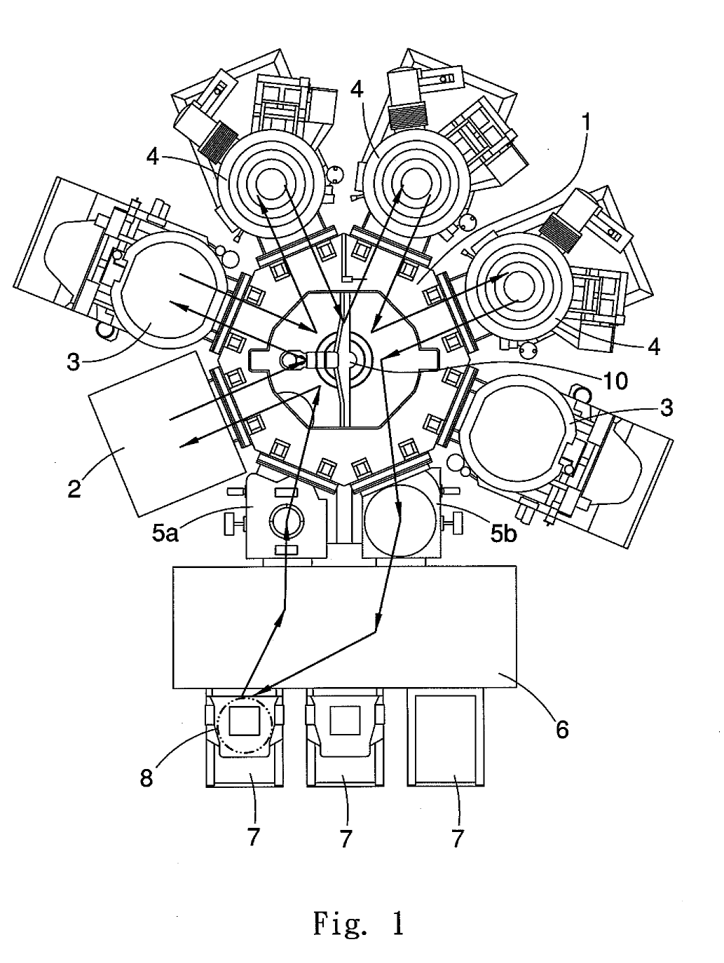

FIG. 2 shows the aluminum adhering method used in the prior metal thin film plating layer machine.

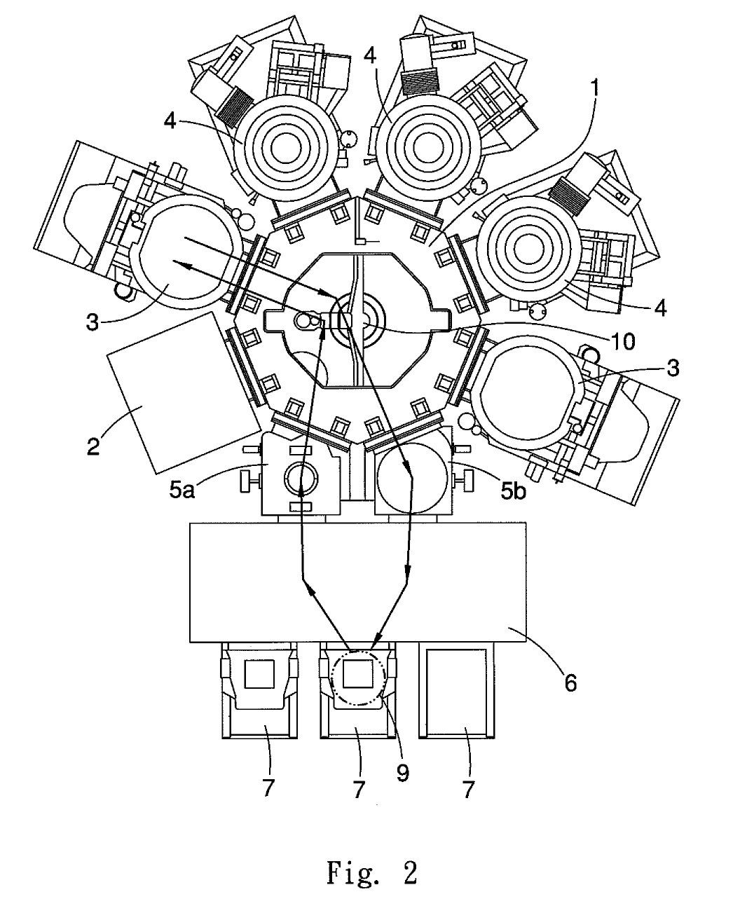

FIG. 3 shows another aluminum adhering method used in the prior metal thin film plating layer machine.

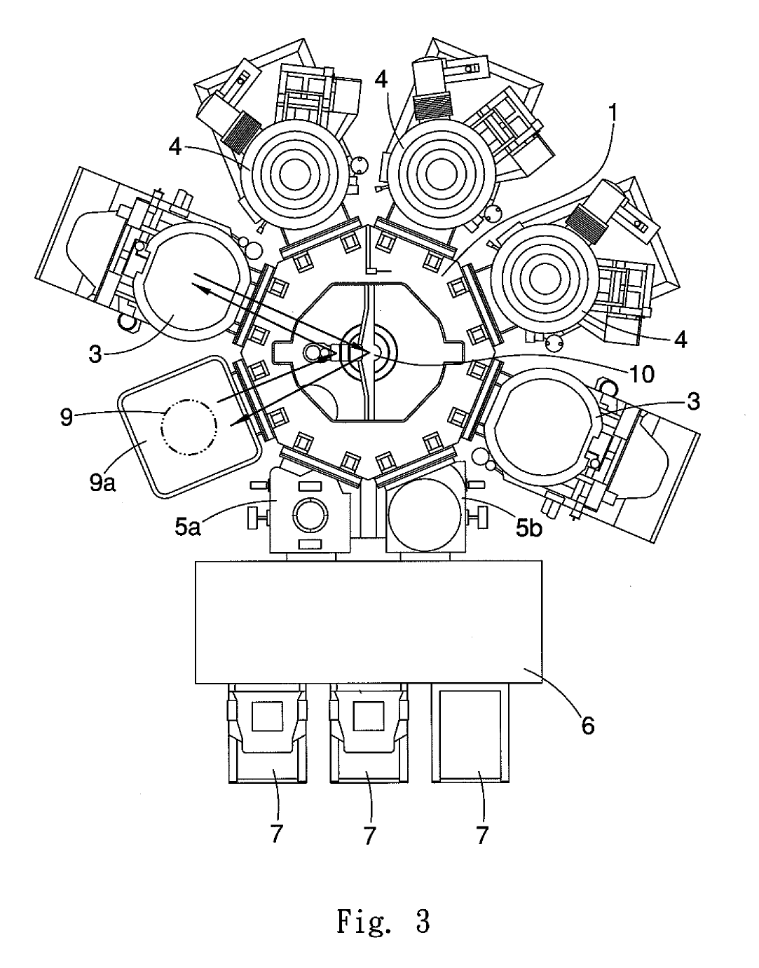

FIG. 4 is a block diagram showing aluminum adhering process according to the present invention

FIG. 5 shows the operation about aluminum adhering process according to the present invention.

FIG. 6 is a block diagram showing aluminum adhering process according to another embodiment of the present invention

FIG. 7 is a partial exploded perspective view about the vacuum transfer chamber of the present invention.

FIG. 8 is an enlarged partial cross sectional view of a locating frame of the present invention.

FIG. 9 shows an operation that an aluminum sheet is taken down from a locating frame according to the present invention.

FIG. 10 is an operational schematic view showing that an aluminum sheet is transferred to a pre etching chamber according to the present invention.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

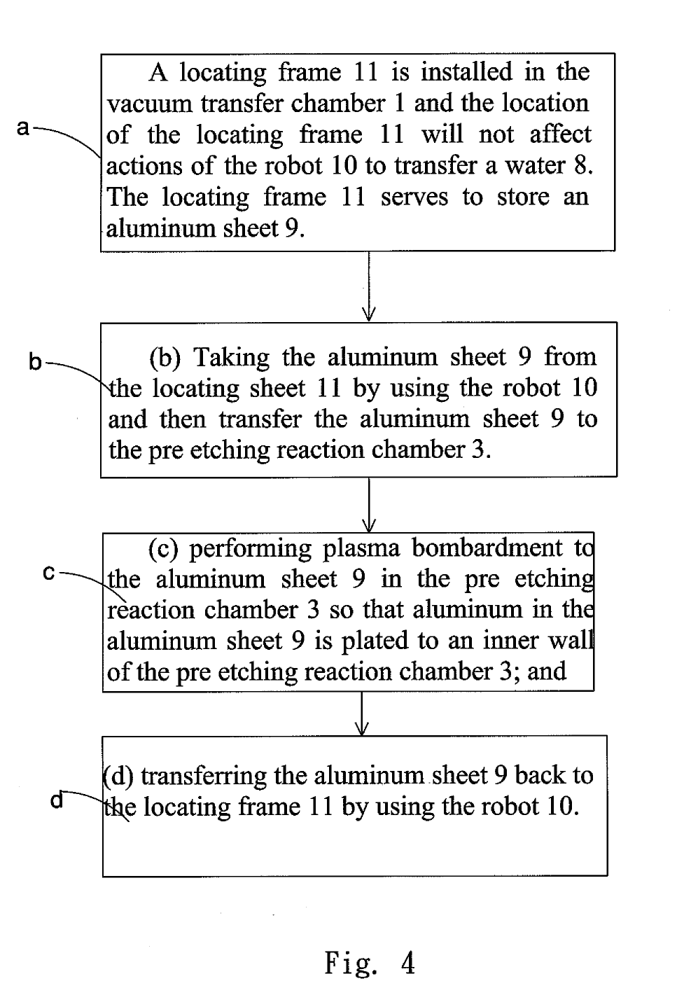

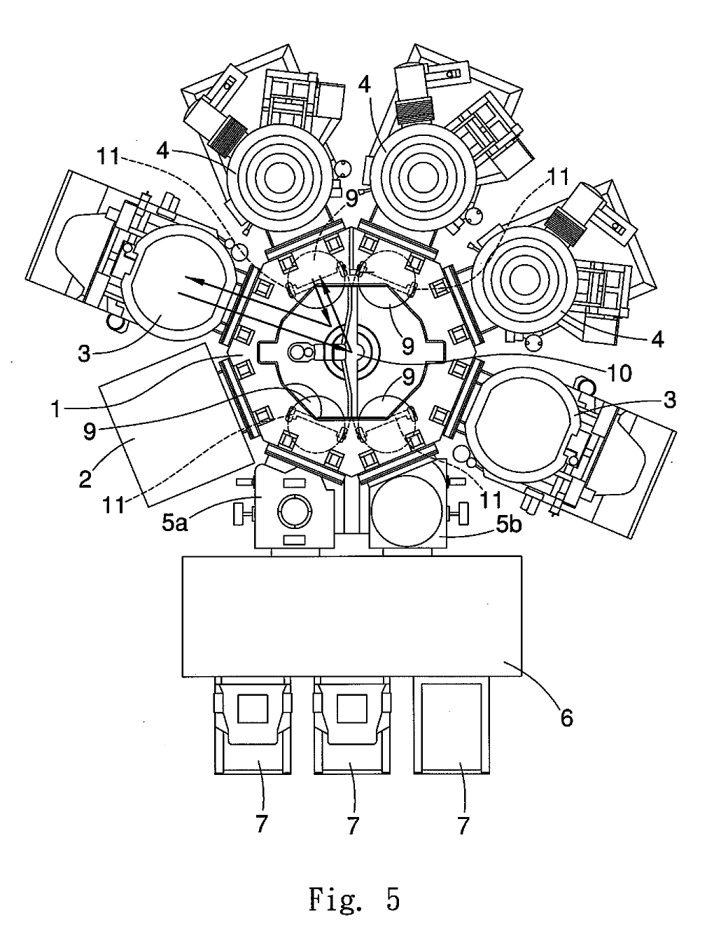

With reference to FIGS. 4 and 5, the structure of the present invention is illustrated. The present invention includes a vacuum transfer chamber 1 and a plurality of pre etching reaction chamber 3s around the vacuum transfer chamber 1 and communicated with the vacuum transfer chamber 1. A robot 10 is installed within the vacuum transfer chamber 1. The method of the present invention includes the following steps:

(a) A locating frame 11 is installed in the vacuum transfer chamber 1 and the location of the locating frame 11 will not affect actions of the robot 10 to transfer a water 8. The locating frame 11 serves to store an aluminum sheet 9.

(b) Taking the aluminum sheet 9 from the locating sheet 11 by using the robot 10 and then transfer the aluminum sheet 9 to the pre etching reaction chamber 3.

(c) performing plasma bombardment to the aluminum sheet 9 in the pre etching reaction chamber 3 so that aluminum in the aluminum sheet 9 is plated to an inner wall of the pre etching reaction chamber 3; and

(d) transferring the aluminum sheet 9 back to the locating frame 11 by using the robot 10.

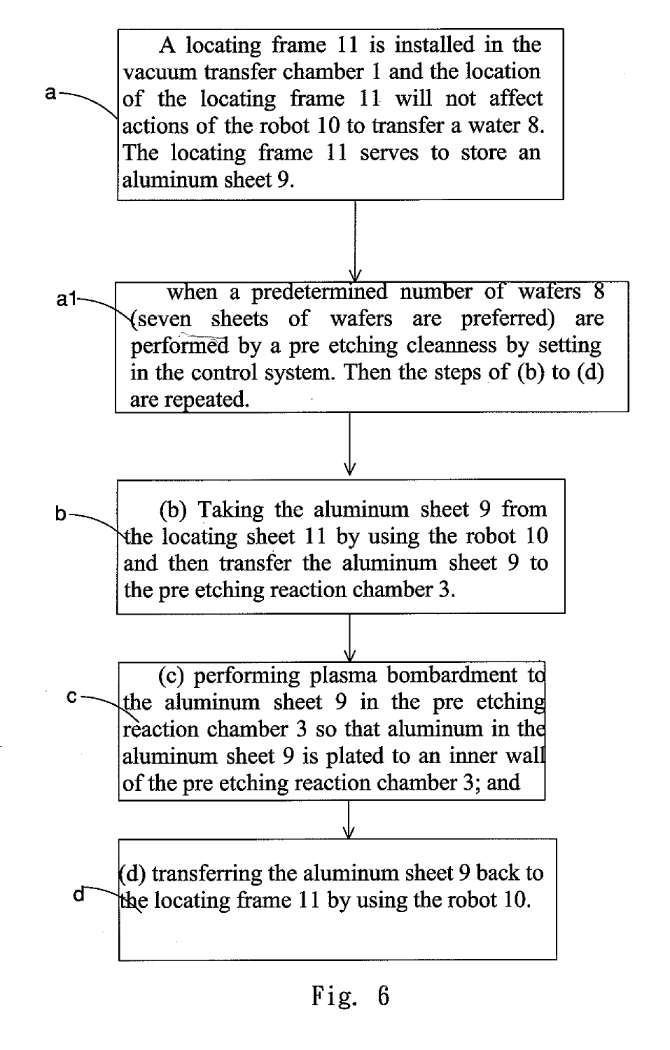

Referring to FIG. 6, the present invention further includes a control system (not shown) for controlling the plating process.

The step (a) further includes a step (a1), in that when a predetermined number of wafers 8 (seven sheets of wafers are preferred) are performed by a pre etching cleanness by setting in the control system. Then the steps of (b) to (d) are repeated.

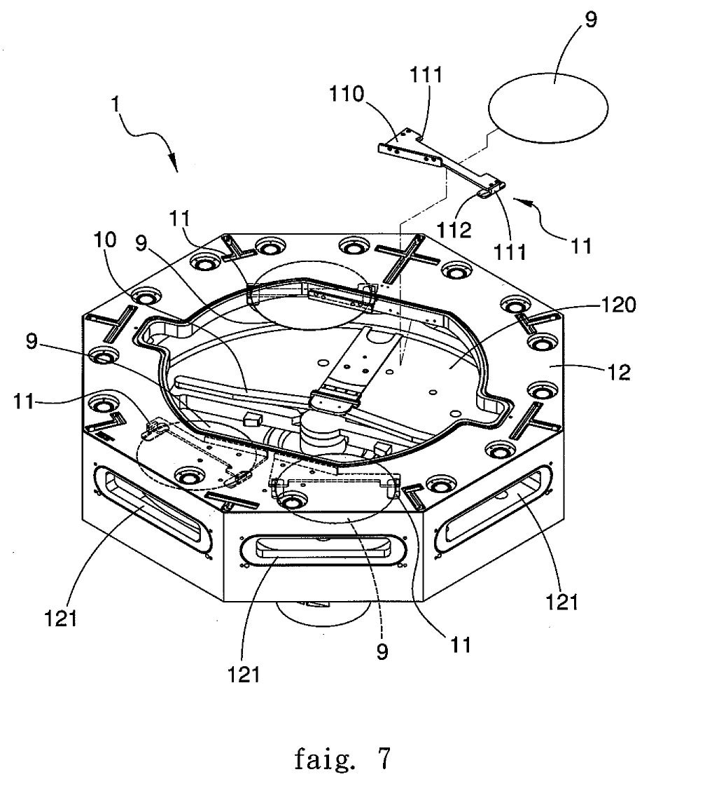

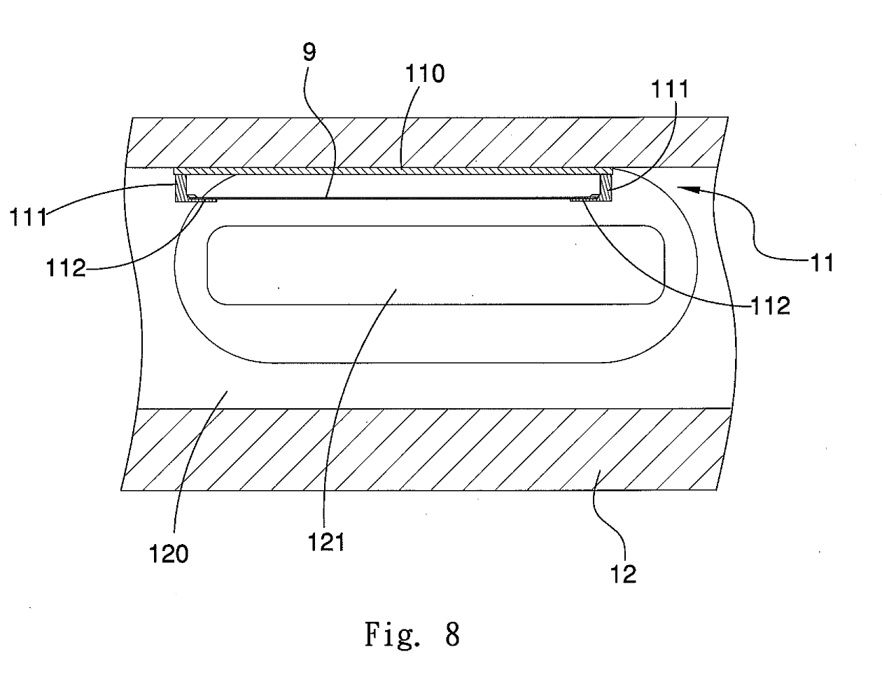

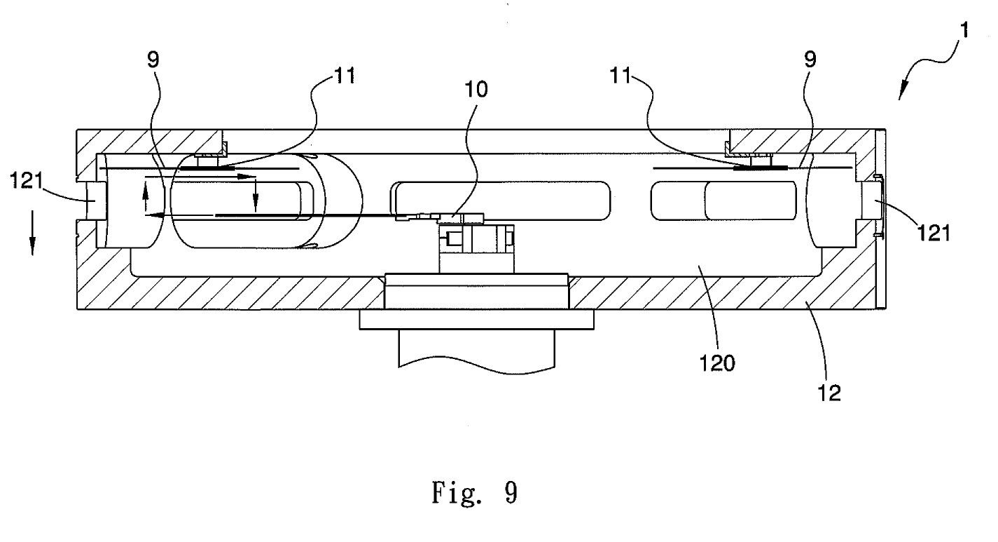

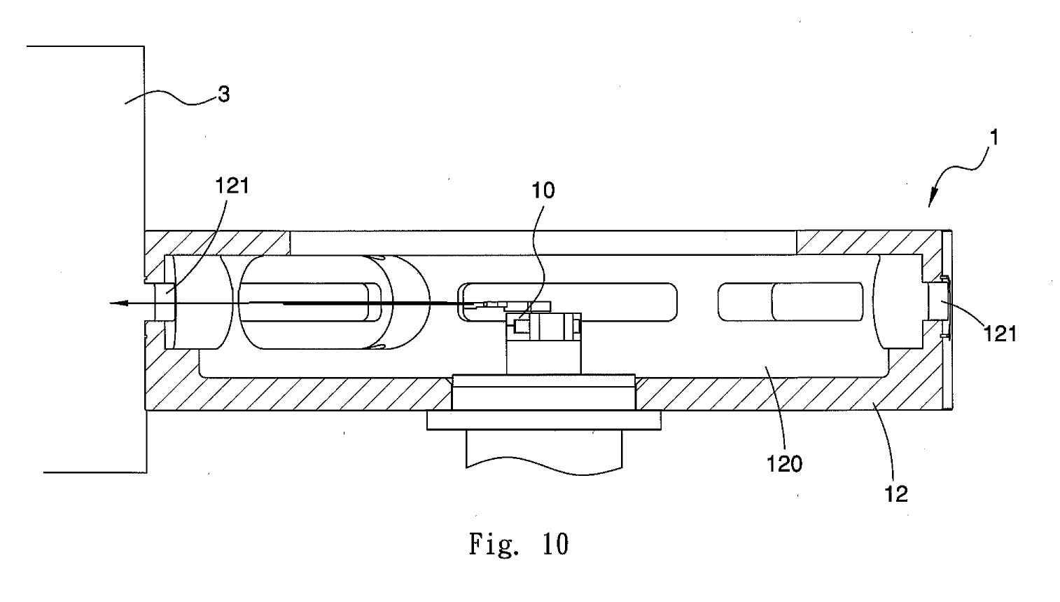

With reference to FIGS. 5 and 7 to 10, in the present invention, the vacuum transfer chamber 1 further includes a chamber body 12, at least one locating frame 11 and a robot 10.

The chamber 12 has a transfer space 120 which is a vacuum space. A periphery of the chamber 120 is formed with a plurality of openings 121 which are communicated to the transfer space 120. One of the openings 121 is communicated with a pre etching reacting cavity 3 which is located at an outer side.

The locating frame 11 is installed in the transfer space 120 and it does not affect the operation of transfer of the wafer 8 by the robot 10. The locating frame 11 includes a retainer 110 and two supporters 111. The retainer 110 is fixedly combined to a top surface of the transfer space 120. The two supporters 111 are formed as an L shape and are formed at two different sides of the retainer 110. Each of the supporter 111 is formed with a supporting portion 112 for supporting an aluminum sheet 9. The aluminum sheet 9 may be a pure aluminum plate, or a wafer with a layer of aluminum being plated thereon.

The robot 10 is installed in the transfer space 120 for transfer of the wafer 8 and serves to take out the aluminum sheet 9 from the locating frame 11 and then transfers the aluminum sheet 9 to the pre etching reacting cavity 3, and could return the aluminum sheet 9 from the pre etching reacting cavity 3 to the locating frame 11.

Preferably, the number of the locating frame 11 is four. Other than installing on the top surface of the transfer space 120 as define in above, the locating frame 11 may be installed on a bottom surface of the transfer space 120, or other portions. Beside, each locating frame 11 may be formed with two layered receiving recesses. For four locating frames 11, there are eight receiving recesses. In the present invention, other than placing the aluminum sheet 9 on the receiving recesses, in manufacturing of wafer 8, the wafer 8 made in the previous process may be placed on the receiving recess. The manufacturing process can be continued because there are sufficient spaces. Therefore, the efficiency can be increased. If the reactor chamber has some problems, the wafer can be stored in the receiving recess temporarily. After the reactor chamber has been repaired, the wafer can be returned to the reactor chamber. The pressure is retained.

The metal thin film plating machine of the present invention needs one time of aluminum adhering process after seven wafers are made. Therefore, four aluminum adhering process is need for 25 wafers. If the thickness of the aluminum sheet is 2.5 mm, the thickness reduction in one plasma bombarding is below 500 A. Therefore, 1 mm thickness of the aluminum sheet 9 can be used through 2000 times. As a result 12500 wafers are made (5000×25). Generally, one maintenance process is needed for cleaning 3000 wafers in the pre etching reacting cavity 3.

When it is needed to replace the aluminum sheet 9, the robot 10 can transfer the unused aluminum sheet 9 out of the second vacuum chamber 5b and then the robot in the normal pressure transfer device 6 transfers it to the wafer transfer box 7. Then the robot in the normal pressure transfer device transfers a new aluminum sheet to the first vacuum chamber 5a. It is further transferred to the locating frame 11 by the robot 10 in the vacuum transfer chamber 1 to complete the update of the aluminum sheet 9 (it needs about 2 minutes). Efficiency of work is not affected.

In the present invention, the aluminum sheet 9 is installed in the locating frame 11 of the vacuum transfer chamber 1 so that in the aluminum adhering process, the operation of vacuuming and restoring pressure do not need and efficiency is increased greatly. Furthermore, the position for storing the aluminum sheet 9 is very near the pre etching reacting cavity 3, and thus in the aluminum adhering process, the distance for transfer of the aluminum sheet 9 is reduced greatly. Especially, the structure of the locating frame 11 is very simple, and thus the cost for making the locating frame 11 is very low. Especially, the locating frame 11 can be directly installed in the vacuum chamber of the metal thin film plating layer machine. No storage chamber for storing the aluminum sheet 9 temporarily is needed. The cost is greatly reduced. Furthermore the opening 121 for vacuum transfer chamber is saved. The system for vacuuming used for the storage chamber is unnecessary and thus the cost is further reduced.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. An aluminum adhering process for a metal thin film plating machine which includes a vacuum transfer chamber and a pre etching reacting cavity which is installed in a periphery of the vacuum transfer chamber and is communicated to the vacuum transfer chamber; the pre etching reacting cavity and the pre etching reacting cavity being in a very high vacuum state; the vacuum transfer chamber being installed with a robot; the aluminum adhering process including the following steps:
(a) installing a locating frame in the vacuum transfer chamber and a location of the locating frame not affect actions of the robot to transfer a water; the locating frame being used to storing an aluminum sheet;
(b) taking the aluminum sheet from the locating sheet by using the robot and then transferring the aluminum sheet to the pre etching reaction chamber;.
(c) plasma bombarding the aluminum sheet in the pre etching reaction chamber so that aluminum in the aluminum sheet is plated to an inner wall of the pre etching reaction chamber; and
(d) transferring the aluminum sheet back to the locating frame by using the robot after a layer of aluminum is plated on the inner wall of the pre etching reacting cavity.

2. The aluminum adhering process for a metal thin film plating machine as claimed in claim 1, wherein the metal thin film plating machine further includes a control system for controlling the plating process; and the step (a) further includes a step (a1), in that when a predetermined number of wafers are processed with a pre etching cleanness, the control system sets to repeat the steps of (b) to (d).

3. The aluminum adhering process for a metal thin film plating machine as claimed in claim 1, wherein the predetermined number is seven.

4. The vacuum transfer chamber for a metal thin film plating machine comprising:
a chamber body having a transfer space which has a vacuum space; a periphery of the chamber being formed with a plurality of openings which are communicated to the transfer space; one of the openings being communicated with a pre etching reacting cavity which is located at an outer side;
a locating frame installed in the transfer space does not affect operations of transfer of the wafer; the locating frame storing at least one aluminum sheet and one wafer; and
a robot installed in the transfer space for transfer of the wafer and for taking out the aluminum sheet from the locating frame and then transferring the aluminum sheet to the pre etching reacting cavity, and could return the aluminum sheet from the pre etching reacting cavity to the locating frame.

5. The vacuum transfer chamber for a metal thin film plating machine as claimed in claim 4, wherein the locating frame has a retainer and two supporters; the retainer is fixedly combined to a top surface of the transfer space; the two supporters are formed at two different sides of the retainer and formed as a receiving recess for receiving an aluminum sheet or the wafer.

6. The vacuum transfer chamber for a metal thin film plating machine as claimed in claim 5, wherein the two supporters are formed as an L shape and are formed at two different sides of the retainer; each of the supporter is formed with a supporting portion for supporting an aluminum sheet or the wafer.

7. The vacuum transfer chamber for a metal thin film plating machine as claimed in claim 4, wherein there are four locating frames.

8. The vacuum transfer chamber for a metal thin film plating machine as claimed in claim 4, wherein the aluminum sheet is a pure aluminum sheet.

9. The vacuum transfer chamber for a metal thin film plating machine as claimed in claim 4, wherein the aluminum sheet is plated on a surface of a wafer.
